(19) United States
(12) Patent Application Publication
(10) Pub. No.: US 2016/0035624 A1
(43) Pub. Date: Feb. 4, 2016

(54) SEMICONDUCTOR DEVICE MANUFACTURING METHOD AND SEMICONDUCTOR DEVICE THEREOF

(71) Applicant: KABUSHIKI KAISHA TOSHIBA, Tokyo (JP)

(72) Inventors: Koji OGISO, Oita (JP); Soichi YAMASHITA, Kanagawa (JP); Kazuhiro MURAKAMI, Yokkaichi Mie (JP)

(21) Appl. No.: 14/883,701

(22) Filed: Oct. 15, 2015

Related U.S. Application Data
(62) Division of application No. 14/015,799, filed on Aug. 30, 2013.

(30) Foreign Application Priority Data
Mar. 19, 2013 (JP) 2013-056586

(51) Int. Cl. H01L 21/768; H01L 23/00; H01L 21/288

(52) U.S. Cl. CPC H01L 21/76898; H01L 21/2885; H01L 21/76873; H01L 24/11; H01L 2224/11462; H01L 2224/11849; H01L 2224/13025; H01L 2224/13082; H01L 2224/1162; H01L 2924/01029; H01L 2924/01028

(57) ABSTRACT

According to one embodiment, a semiconductor device manufacturing method provides filling a through-hole which penetrates through a first side of substrate to a second side thereof. A seed film including copper is formed on the inner wall surface of the through-hole. A first metal layer including copper is grown bottom-up from one end of the through-hole toward the other end thereof, to partially fill the through-hole, leaving a space having a depth less than the radius of the through-hole as measured from the second side surface of the substrate. A second metal layer including nickel is conformally grown in the space from the inner peripheral surface of the through-hole to a height having a summit surface protruding from the second side surface of the substrate. A third metal layer is formed on the summit surface of the second metal layer.

### CROSS-REFERENCE TO RELATED APPLICATION

This application is a divisional of U.S. patent application Ser. No. 14/015,799, filed Aug. 30, 2013, which application is based upon and claims the benefit of priority from Japanese Patent Application No. 2013-056586, filed, Mar. 19, 2013, the entire contents of both applications being incorporated herein by reference.

### FIELD

Embodiments described herein relate generally to a semiconductor device manufacturing method and a semiconductor device thereof.

### BACKGROUND

Conventionally, a technique for decreasing the size of a semiconductor device has been used wherein multiple chips are stacked with a semiconductor element and an integrated circuit formed on a substrate. The stacked chips are mutually connected by through-electrodes penetrating the substrate. The through-electrode is formed, for example, by filling the through-hole penetrating across the substrate with a metal by an electrolytic plating process.

However, when using this technique, there is a possibility of generating a space or void inside a through-electrode when forming the through-electrode by the electrolytic plating process. This void becomes one of the causes of failure of the device by reducing the conductivity of the through-electrode.

### DESCRIPTION OF THE DRAWINGS

FIG. 1 is a side cross-sectional view for describing a semiconductor device according to an embodiment.

FIGS. 2A to 2C are side cross-sectional views for describing a manufacturing process of the semiconductor device according to the embodiment.

FIGS. 3A and 3B are side cross-sectional views for describing the manufacturing process of the semiconductor device according to the embodiment.

FIGS. 4A and 4B are side cross-sectional views for describing the manufacturing process of the semiconductor device according to the embodiment.

FIGS. 5A and 5B are side cross-sectional views for describing the manufacturing process of the semiconductor device according to the embodiment.

### DETAILED DESCRIPTION

In general, according one embodiment, a semiconductor device manufacturing method and a semiconductor device thereof capable of restraining the generation of a void inside a through-electrode is provided.

According to one embodiment, a semiconductor device manufacturing method is provided. In the semiconductor device manufacturing method, a through-hole penetrating across a substrate and reaching a conductive film on a back surface of the substrate is formed. A seed film, including copper on an inner wall surface of the through-hole, a surface of the conductive film exposed within the through-hole, and a surface of the substrate, is formed. Using an electrolytic plating method, a first metal layer including copper is grown bottom-up from one end surface of the through-hole penetrating across the substrate toward the other end surface thereof, to fill the through-hole, leaving a space in the through-hole, the space having a depth less than the radius of the through-hole as measured from the other end surface. Using the electrolytic plating method, a second metal layer including nickel is conformally grown in the space from the inner peripheral surface of the through-hole, in a manner that the summit surface (top surface) of the second metal layer protrudes from the other end surface. A third metal layer is formed on the summit surface of the second metal layer. The seed film is etched with the third metal layer as a mask. The third metal layer is thermally fused in shape.

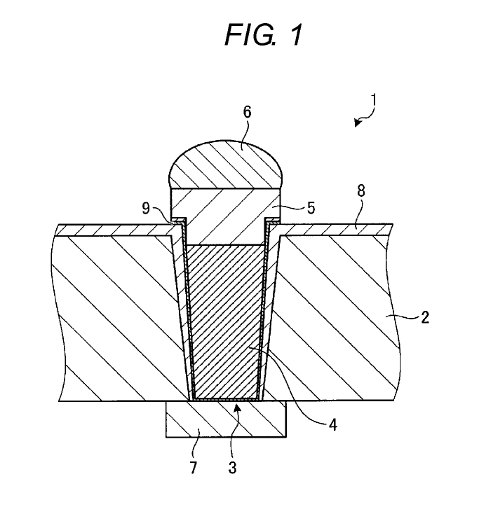

Hereinafter, a semiconductor device manufacturing method and a semiconductor device thereof according to the embodiment will be described in detail with reference to the attached drawings. This embodiment is not intended to restrict the disclosure. FIG. 1 is a side cross-sectional view for describing a semiconductor device according to the embodiment. FIG. 1 schematically shows a cross section of a portion of a through-electrode 1 which penetrates across a substrate 2 in a semiconductor device.

As illustrated in FIG. 1, a semiconductor device according to the embodiment has the through-electrode 1 which penetrates across the substrate 2. Specifically, the through-electrode 1 includes, for example, a first metal layer 4 which partially fills a through-hole (hereinafter, referred to as “via 3”) penetrating across (i.e., through) the substrate 2, such as a silicon wafer, from one end surface (a first major surface; here, the bottom surface). The first metal layer 4 may be deposited up to a depth D that is substantially halfway to about less than the radius R of the via 3 relative to the other end surface (a second major surface; here, the top surface).

Further, the through-electrode 1 includes a second metal layer 5 which covers the first metal layer 4 from the depth up to the top surface of the via 3 in such a manner that forms a summit surface protruding from the top surface of the via 3. The through-electrode 1 also includes a bump 6 including a third metal layer which is formed on the summit surface of the second metal layer 5 by thermofusion (fusing (or melting) under high temperature condition). Here, an insulating film 8 and a copper film 9 are provided between an inner peripheral surface of the via 3 and the through-electrode 1 and an electrode 7 is provided on the bottom surface of the through-electrode 1.

The first metal layer 4 in the through-electrode 1 is formed, for example, by depositing copper from the bottom surface of the via 3 upwardly. According to this, a void can be prevented from generating inside the first metal layer 4.

Further, the second metal layer 5 is formed, for example, by depositing nickel from the surface of the first metal layer 4 in the via 3 and the peripheral surface of the via 3 to fill the via 3 and form the summit surface. According to this, a void can be restrained from generating inside the second metal layer 5 and the height of the summit surface of the second metal layer 5 can be controlled with high precision.

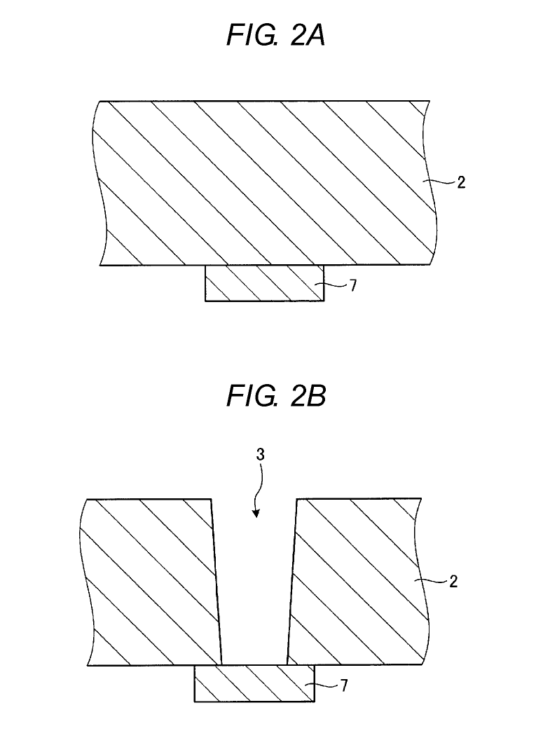

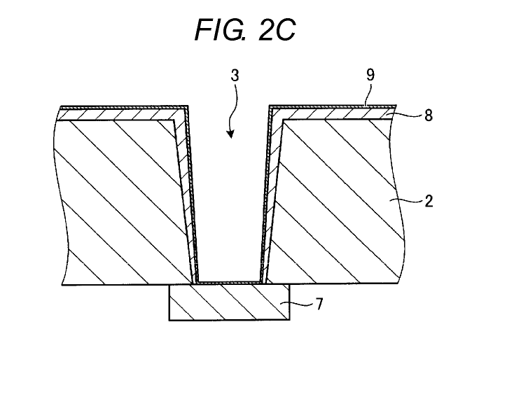

Hereinafter, an example of the manufacturing process of forming the through-electrode 1 will be specifically described with reference to FIGS. 2A to 5B. FIGS. 2A to 5B are views for use in describing a manufacturing method of a semiconductor device according to the embodiment. In FIGS. 2A to 5B, a schematic cross section of the region where the through-electrode 1 is formed is selectively shown and other portions are omitted.

As illustrated in FIG. 2A, in the manufacturing method of a semiconductor device according to the embodiment, for example, the substrate 2 such as a silicon wafer with a semiconductor element such as a semiconductor memory is prepared. Then, on a first major surface (here, the bottom surface) of the substrate 2 at a predetermined position, the electrode 7 comprising a patterned gold conductive film, or the like, is provided.

Continuously, as illustrated in FIG. 2B, the via 3 penetrating across the substrate 2 is formed from the second major surface (here, the top surface) of the substrate 2 toward the first major surface thereof, to expose the top surface of the electrode 7. As illustrated in FIG. 2C, an insulating film 8 such as a silicon oxide film is formed, for example, by a sputtering method, on the inner peripheral surface of the via 3 and the top surface of the substrate 2.

Then, after the top surface of the electrode 7 is exposed again by eliminating the insulating film 8 formed on the top surface of the electrode 7, a copper film 9, which becomes a seed film for the electrolytic plating, is formed, for example, by sputtering, on the surface of the insulating film 8. The copper film 9 is only one example of the seed film, and any thin film may be used other than the copper film 9 as long as it includes copper being formed on the inner wall surface of the through-hole 3, the exposed surface of the electrode 7 within the via 3, and the surface of the substrate 2.

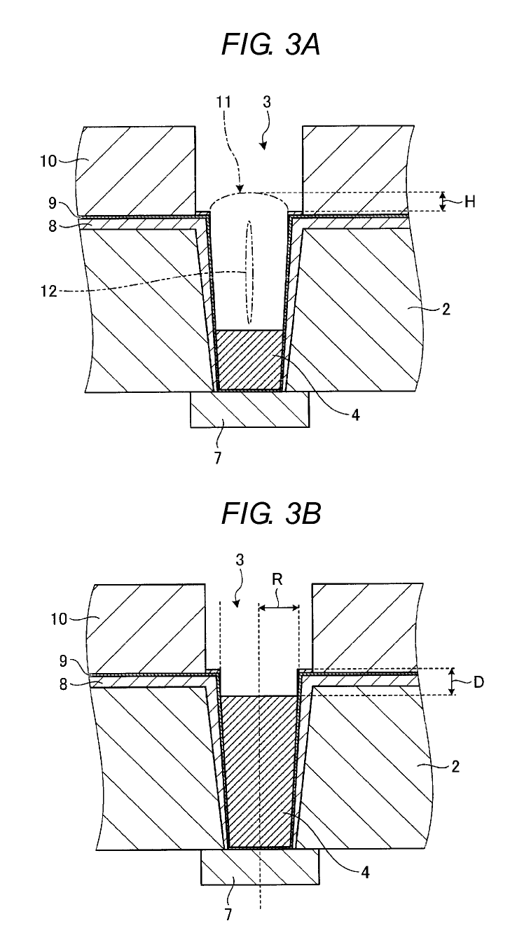

Continuously, as illustrated in FIG. 3A, after a resist 10 is formed on the top surface of the substrate 2, the resist 10, corresponding to the position of the via 3, is selectively eliminated. Here, the resist 10 includes an opening overlying the via 3 having a dimension (diameter) greater than a diameter of the via 3. The remainder of the resist 10 is left on the top surface of the substrate 2.

Then, metal is deposited into the via 3, whose inner peripheral surface is covered with the copper film 9, through an electrolytic plating method. Here, the electrolytic plating method for filling the via 3 with metal includes two types of plating: “Bottom-Up” and “Conformal”.

The bottom-up plating is a method of sequentially growing a metal layer from one end surface that becomes the bottom surface of the via 3 toward the other end surface that becomes an upper opening, in order to fill the via 3 with metal. In the bottom-up plating method, by adding an additive including a detergent (surfactant) for restraining the plating metal from adhering to the inner surface of the via 3 to an electrolytic solution used for the plating, the metal layer is grown from the bottom of the via 3 upwards.

According to the bottom-up plating method, generation of a void inside the through-electrode 1 can be restrained. However, when the entire volume of the via 3 is filled by the bottom-up plating method, the metal layer is expanded in a dome shape upwardly from the upper opening of the via 3, hence to form an overburden 11, as illustrated by the dashed line in FIG. 3A.

When a plurality of vias 3 are filled at once through the bottom-up plating method, the respective overburdens 11 formed on the upper openings of the respective vias 3 are different in height H depending on the respective vias 3. Further, it is very difficult to control the uniformity of the heights H of the overburdens 11.

Therefore, when a plurality of vias 3 are filled at the same time by the bottom-up plating method, the heights of the respective bumps 6 (shown in FIG. 1) formed on the metal layers, which fill the vias 3, become uneven and may cause a connection failure between a chip to be stacked later on the bumps 6. Further, the bottom-up plating method disadvantageously takes much more time to fill the via 3 with the metal layer, compared with the conformal plating method.

On the other hand, the conformal plating is a plating method of growing the metal layer from the inner peripheral surface of the via 3, including the bottom surface of the via 3, in order to fill the via 3 with metal. By adopting the conformal plating method, it takes less time to finish filling the via 3 with the metal layer than in the case of the bottom-up plating method.

However, when using the conformal plating method, the metal layer grows faster in the upper opening portion than in the inner lateral surface of the via 3 due to an electric field concentrated at the corner (edge) of the upper opening of the via 3. Therefore, when the whole via 3 is filled according to the conformal plating, the upper opening of the via 3 may be closed by the metal layer before the inside of the via 3 is filled with the metal layer, which causes the generation of a void 12 inside the via 3, as illustrated by the double-dashed line in FIG. 3A.

According to the embodiment, as illustrated in FIG. 3A, at first, the bottom-up plating method is used to start the bottom-up growth of the first metal layer 4 from the bottom surface of the via 3. Here, the first metal layer 4 is formed, for example, by growing a metal layer including copper. Then, the first metal layer 4 partially fills the via 3 from the bottom surface to a depth less than the entire depth of the via 3, thereby concluding the bottom-up plating of the metal.

Specifically, as illustrated in FIG. 3B, the via 3 is filled with the first metal layer 4 from the bottom surface partially to a depth D, spaced from the upper opening surface of the via 3, that is less than a radius R of the via 3, thereby concluding the bottom-up plating.

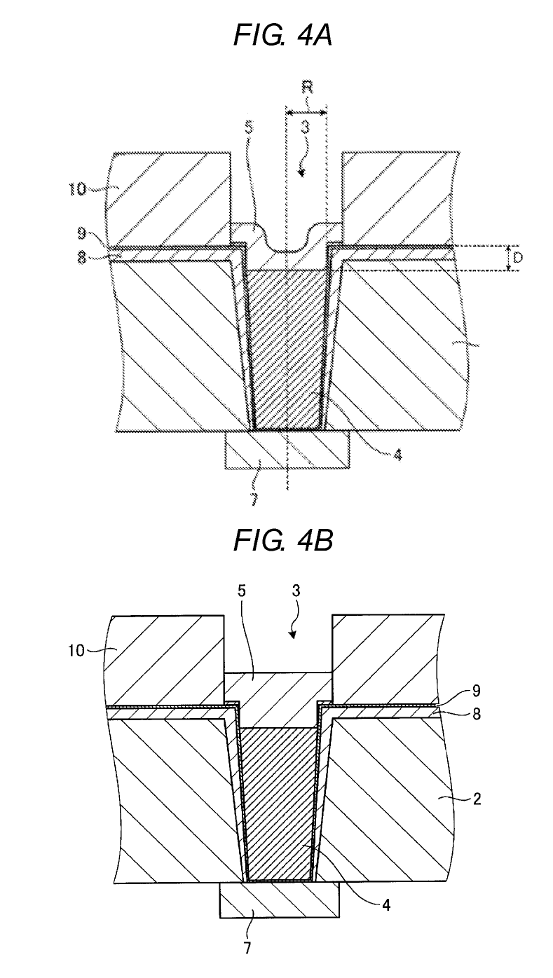

Continuously, as illustrated in FIG. 4A, the conformal plating method is started to conformally grow the second metal layer 5 from the inner peripheral surface of the via 3 which has been filled with the first metal layer 4 to the depth D. Here, the second metal layer 5 is formed, for example, by growing a metal layer including nickel on the first metal layer 4.

Here, the depth D of the via 3, which is filled according to the conformal plating method, is less than the radius R of the via 3, as mentioned above. Therefore, even if the second metal layer 5 conformally grows faster at the edge of the upper opening of the via 3 as compared to the growth from the inner lateral surface of the via 3, the via 3 is filled before the upper opening of the via 3 is closed by the second metal layer 5, thereby restraining the generation of a void. Here, the depth D of the via 3 filled through the conformal plating may be deeper than the radius R of the via 3 as long as the depth is such that the generation of a void in the second metal layer 5 can be minimized.

As mentioned above, the remaining portion of the via 3 having the first metal layer 4 deposited by the bottom-up plating method is filled using the conformal plating method; therefore, compared with the case of filling the whole via 3 by the bottom-up plating, it can finish the filling of the via 3 in a shorter time period.

Then, the conformal plating method is continued to fill the via 3 and, as illustrated in FIG. 4B, the summit surface of the second metal layer 5 protrudes from the upper opening surface of the via 3 at a predetermined height, which concludes the conformal plating of the second metal layer 5. By adopting the conformal plating method, as the summit surface of the second metal layer 5 is protruded from the upper opening surface of the via 3, the height of the summit surface of the second metal layer 5 can be controlled at greater precision, as compared with the case of the bottom-up plating method.

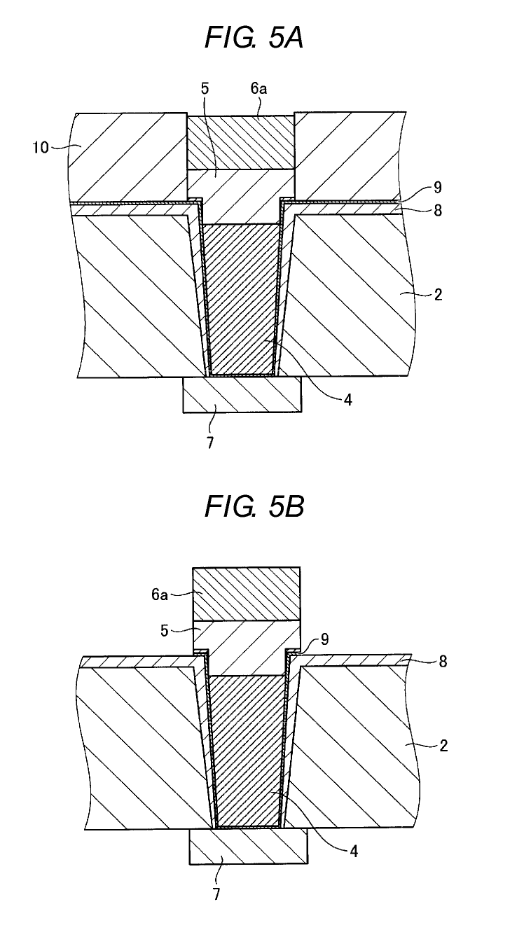

Next, as illustrated in FIG. 5A, a third metal layer 6a is formed on the second metal layer 5. Here, the third metal layer 6a is a metal layer which can be formed by thermofusion; for example, it is formed of tin.

Thereafter, as illustrated in FIG. 5B, after removing the resist 10, the copper film 9 formed on the substrate 2 is removed by wet etching with the second metal layer 5 and the third metal layer 6a protruding from the upper opening surface of the via 3 used as a mask.

In the wet etching, a chemical solution is used that can etch the copper but cannot etch the nickel. According to this, the second metal layer 5, that is the base (POST) of the third metal layer 6a, is protected from being etched. Accordingly, it is possible to inhibit a deterioration in the conductivity and the mechanical integrity of the device caused by a reduction in the diameter of the second metal layer 5.

Lastly, a reflow process is performed, and the third metal layer 6a is fused to be formed in a substantially hemispherical shape in order to form the bump 6 (shown in FIG. 1). According to this, a semiconductor device shown in FIG. 1 is manufactured.

As mentioned above, according to the embodiment, the portion from the bottom surface of the via 3 to the about the one-half of the through-hole penetrating across the substrate is filled with the first metal layer formed by a bottom-up plating method. The bottom-up plating method is concluded leaving a space in the via 3 above the first metal layer 4. This can inhibit a void from generating inside the first metal layer during fill of a portion of the through-hole.

Further, according to the embodiment, the through-hole filled with the first metal layer from its bottom surface to the one-half is filled with the second metal layer by a conformal plating method, and further, the summit surface of the second metal layer is protruded from the through-hole. This can control the height of the summit surface in the second metal layer at high precision as well as restrain a void from generating inside the second metal layer.

Furthermore, according to the embodiment, a bump is formed on the summit surface of the second metal layer by thermally fusing the third metal layer. This can connect the stacked semiconductor devices very easily just by stacking the semiconductor devices according to the embodiment and heating the stacked semiconductor devices in order to electrically interconnect the devices.

Further, since copper, which has been generally used as the material of a through-electrode, is used to form a first metal layer, it is possible to form the first metal layer without significantly changing the conventional manufacture process. Further, by using nickel as the material of a second metal layer, the lateral surface of the second metal film can be protected from etching, in the process of eliminating the copper film remaining on the substrate surface through the wet etching. Therefore, it is possible to minimize deterioration of the conductivity of the second metal layer as well as the mechanical integrity of the device.

In the process of forming a first metal layer, the first metal layer partially fills the through-hole from the bottom surface to leave a space from the upper opening surface of the through-hole having a depth less than the radius of the through-hole. When the through-hole that is partially filled with the first metal layer is then filled with the second metal layer formed according to the conformal plating, a void can be restrained from generating inside the second metal layer more dependably.

In the embodiment, although the seed film for the plating is formed in a single structure of the copper film 9, it may be formed in a multi-layer structure by sequentially forming, for example, a titanium film and a copper film on the surface of the insulating film 8 covering the inner peripheral surface of the via 3. Further, the insulating film 8 covering the inner peripheral surface of the via 3 may be formed in a multi-layer structure by sequentially forming, for example, a silicon nitride film and a silicon oxide film. In the embodiment, although the through-electrode 1 is formed after forming the electrode 7, the electrode 7 may be formed after forming the through-electrode 1.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device manufacturing method, comprising:
forming a conductive film on a first surface of a substrate;
forming a through-hole extending through the substrate from a second surface thereof to expose the conductive film on the first surface of the substrate;
depositing a seed film on an inner wall of the through-hole, a surface of the conductive film exposed in the through-hole, and the second surface of the substrate;
depositing a first metal layer from a first end of the through-hole adjacent to the conductive film toward a second end thereof by a bottom-up electrolytic plating method to fill a volume of the through-hole to a depth position; and
depositing a second metal layer on an inner peripheral surface of the through-hole from the depth position by a conformal electrolytic plating method to forma summit surface that protrudes from the second surface.

2. The semiconductor device manufacturing method according to claim 1, further comprising:
depositing a third metal layer on the summit surface of the second metal layer.

3. The semiconductor device manufacturing method according to claim 2, wherein
the third metal layer is formed by thermofusion.

4. The semiconductor device manufacturing method according to claim 2, further comprising:
etching the seed film using the third metal layer as a mask.

5. The semiconductor device manufacturing method according to claim 1, wherein
the first metal layer includes copper, and
the second metal layer includes nickel.

6. The semiconductor device manufacturing method according to claim 5, wherein
the seed film includes copper.

7. The semiconductor device manufacturing method according to claim 5, wherein
a distance from the second surface of the substrate to the depth position is less than a radius of the through-hole measured at the second surface of the substrate.

8. The semiconductor device manufacturing method according to claim 1, wherein
a distance from the second surface of the substrate to the depth position is less than a radius of the through-hole measured at the second surface of the substrate.

9. A semiconductor device manufacturing method, comprising:
forming a conductive film on a first surface of a substrate;
forming a through-hole extending through the substrate from a second surface thereof to expose the conductive film on the first surface of the substrate;
depositing a seed film on an inner wall of the through-hole, a surface of the conductive film exposed in the through-hole, and the second surface of the substrate;
depositing a first metal layer from a first end of the through-hole adjacent to the conductive film toward a second end thereof by a bottom-up electrolytic plating method to fill the through-hole to a depth position;
depositing a second metal layer on an inner peripheral surface of the through-hole from the depth position by a conformal electrolytic plating method to forma summit surface that protrudes from the second surface;
depositing a third metal layer on the summit surface of the second metal layer; and
etching the seed film using the third metal layer as a mask.

10. The semiconductor device manufacturing method according to claim 9, wherein
a distance from the second surface of the substrate to the depth position is less than a radius of the through-hole measured at the second surface of the substrate.

11. The semiconductor device manufacturing method according to claim 9, wherein
the first metal layer includes copper, and
the second metal layer includes nickel.

12. The semiconductor device manufacturing method according to claim 11, wherein
the depth position is a depth that is less than a radius of the through-hole measured at the second surface of the substrate.

13. The semiconductor device manufacturing method according to claim 11, wherein
the seed film includes copper.

14. The semiconductor device manufacturing method according to claim 13, wherein
a distance from the second surface of the substrate to the depth position is less than a radius of the through-hole measured at the second surface of the substrate.

15. The semiconductor device manufacturing method according to claim 9, wherein
the third metal layer is formed by thermofusion.

16. A semiconductor device manufacturing method, comprising:
forming a conductive film on a first major surface of a substrate;
forming a through-hole extending through the substrate from a second major surface of the substrate to expose the conductive film on the first major surface of the substrate;
depositing a seed film including copper on an inner peripheral wall of the through-hole, a surface of the conductive film exposed in the through-hole, and the second major surface of the substrate;
depositing a first metal layer including copper from a first end of the through-hole adjacent to the conductive film toward a second end thereof by a bottom-up electrolytic plating method to fill a volume of the through-hole to a depth position that is between the first and second major surfaces of the substrate;
depositing a second metal layer including nickel on an inner peripheral surface of the through-hole from the depth position by a conformal electrolytic plating method to form a summit surface that protrudes from the second major surface;
depositing a third metal layer on the summit surface of the second metal layer; and
etching the seed film using the third metal layer as a mask.

17. The semiconductor device manufacturing method according to claim 16, wherein
the third metal layer is formed by thermofusion.

18. The semiconductor device manufacturing method according to claim 16, wherein
a distance from the second major surface of the substrate to the depth position is less than a radius of the through-hole measured at the second major surface of the substrate.

19. The semiconductor device manufacturing method according to claim 16, wherein
wherein the seed film deposited on the second major surface has a dimension that is substantially the same as a dimension of the summit surface.

20. The semiconductor device manufacturing method according to claim 16, further comprising
forming an insulating film on the second major surface of the substrate and the inner peripheral wall of the through-hole prior to depositing the seed film.
